(19) United States
(12) Patent Application Publication
(10) Pub. No.: US 2009/0001541 A1
(43) Pub. Date: Jan. 1, 2009

(54) Method and apparatus for stackable modular integrated circuits

(75) Inventors: James B. Covert, Wheaton, IL (US); David S. Trollope, Naperville, IL (US)

Correspondence Address: FAY SHARPE/LUCENT, 1100 SUPERIOR AVE, SEVENTH FLOOR, CLEVELAND, OH, 44114, US

(73) Assignee: Lucent Technologies Inc.

(21) Appl. No.: 11/824,351

(22) Filed: Jun. 29, 2007

(51) Int. Cl. H01L 23/02; H01L 21/44

(52) U.S. Cl. 257/686; 438/109; 257/E23.02; 257/E23.18

(57) ABSTRACT

Systems and methods for vertically stacking integrated circuit (IC) modules on a motherboard to conserve motherboard space and reduce power consumption are disclosed. IC modules can comprise processor circuitry, memory elements, communication circuitry, etc. Pins on each IC module can be directly inserted into lower IC module or into a socket layer that couples the IC modules. Heat generated by the IC modules can be dissipated by inserting heat dissipation layers into the vertical stack, between IC modules, or by placing a heat-dissipating sleeve around the stack. The IC modules themselves and/or heat-generating regions therein may be misaligned on their respective socket layers to further facilitate dissipating heat. Module stacks are scalable in that a user may add memory and/or processor modules as desired to increase device capability.

### BACKGROUND OF THE INVENTION

By way of background, conventional computing device motherboard layouts involve arranging a plurality of ICs in parallel, such as in a single plane on a surface of the motherboard. In such arrangements, circuit layout is constrained to a single layer of IC components, with convoluted interconnections that require substantial advanced planning in order to determine a layout design that efficiently utilizes available space. Moreover, even a well designed single-layer layout often requires connections between IC components located at disparate areas on the motherboard, increasing cost and heat generation as power is dissipated in the connecting lines.

Another disadvantage of conventional single-layer motherboard layouts is limited scalability. Although many motherboards can be upgraded by replacing dated memory cards with limited capacity with new memory cards of higher capacity, replacing a processor typically involves an expert technician and is often cost-prohibitive. Additionally, upgrading an out-dated motherboard is further limited by the spatial capacity of the single-layer motherboard, the heat-dissipating abilities of the tower or device in which the board is located, and the like.

There is an unmet need in the art for systems and methods that resolve the above-referenced deficiencies and others.

### SUMMARY OF THE INVENTION

A method and apparatus for stacking modular integrated circuits (ICs), with inter-processor buses there between, on a motherboard are provided.

In one aspect of the invention a stackable integrated circuitry (IC) module system comprises a motherboard on which at least one IC module stack is constructed, a plurality of IC modules coupled together to form the at least one IC module stack, which is coupled to the motherboard, and an inter-processor bus that is formed by connecting pins of two or more IC modules.

According to another aspect, a method of scalably stacking IC modules on a motherboard comprises selecting at least two IC modules to be vertically stacked on the motherboard, evaluating heat dissipation constraints for the IC modules, inserting a heat dissipating element above or below an IC module that produces heat above a predetermined acceptable threshold level, if present, and coupling the IC modules and optional heat dissipating element into a vertical stack on the motherboard.

According to another aspect, a system for vertically stacking IC modules on a motherboard comprises a plurality of stackable IC modules, means for connecting the IC modules into a first vertical stack, means for communicating between modules within the first vertical stack and with modules in at least a second vertical stack, means for coupling the first and second vertical stacks to the motherboard, and means for dissipating heat generated by modules in the first and second vertical stacks.

An advantage of the various aspects described herein is that device size can be reduced by stacking multiple IC modules vertically in a single locus on the motherboard.

Another advantage resides in reduced power levels for inter-module communication, since the pins on respective modules form an inter-module bus that is significantly shorter than interconnection lines that would coupled the modules if laid out in a flat or parallel layout using conventional systems and methods.

Another advantage is that the stackable IC module designs are scalable, such that a user can add any desired number of processor or memory modules to increase processing power or memory capacity over the life of the device, without having to remove other modules or reconfigure the vertical stacks.

Further scope of the applicability of the present invention will become apparent from the detailed description provided below. It should be understood, however, that the detailed description and specific examples, while indicating preferred embodiments of the invention, are given by way of illustration only, since various changes and modifications within the spirit and scope of the invention will become apparent to those skilled in the art.

### DESCRIPTION OF THE DRAWINGS

The present invention exists in the construction, arrangement, and combination of the various parts of the device, and steps of the method, whereby the objects contemplated are attained as hereinafter more fully set forth, specifically pointed out in the claims, and illustrated in the accompanying drawings in which:

FIG. 1 illustrates an IC component that includes a plurality of pins that are inserted into receiving channels in an IC socket on a motherboard;

FIG. 2 illustrates a plurality of the IC components arranged on a motherboard, with a plurality of interconnections that connect respective pins according to a desired layout;

FIG. 3 illustrates an IC component stack that comprises a plurality of IC component modules, which can be connected vertically to reduce interconnection distance and overall device size by mitigating a need for parallel component layout;

FIG. 4 is an illustration of a plurality of stacks of modules on the motherboard, such as can be constructed using the systems and methods described herein;

FIG. 5 illustrates a plurality of layers for a stack of IC component modules, such as may be employed in conjunction with various aspects described herein;

FIG. 6 illustrates an additional or alternative manner of stacking layers and IC modules, in accordance with various aspects described herein;

FIG. 7 illustrates another manner in which modules and socket layers can be stacked to facilitate heat dissipation, in accordance with various aspects.

FIG. 8 is an illustration of a further aspect that facilitates heat dissipation, in accordance with one or more features.

FIG. 9 is an illustration of a method of scalably stacking IC components on a motherboard while providing for heat dissipation, in accordance with various aspects described herein; and

FIG. 10 is an illustration of a method for constructing an IC component stack on a motherboard to minimize motherboard size and reduce interconnection length and power dissipation in a device, in accordance with one or more aspects.

### DETAILED DESCRIPTION

This invention relates to a method and apparatus for stacking modular integrated circuits (ICs), with inter-processor buses there between, on a motherboard.

While the invention is particularly directed to the art of computing devices, and will be thus described with specific reference thereto, it will be appreciated that the invention may have usefulness in other fields and applications. For example, the invention may be used in communication devices, gaming devices, or any other devices in which it is desirable to reduce size, increase processing power and/or memory, etc.

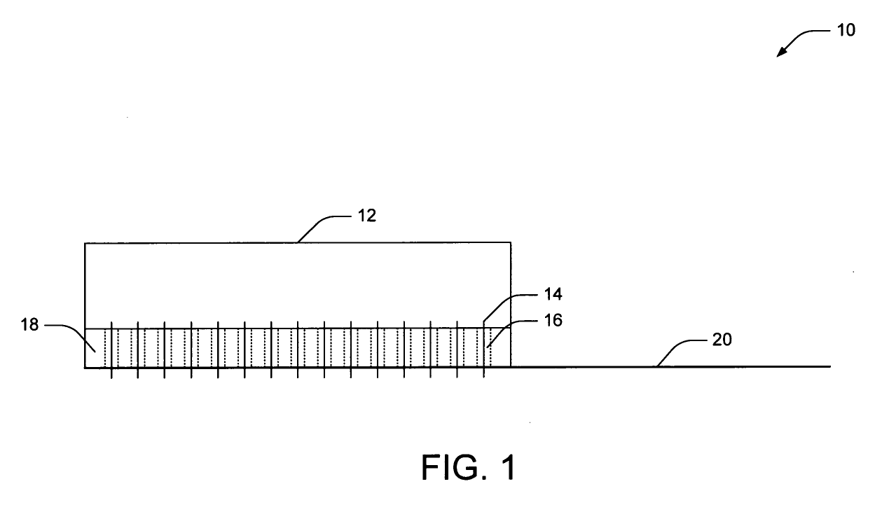

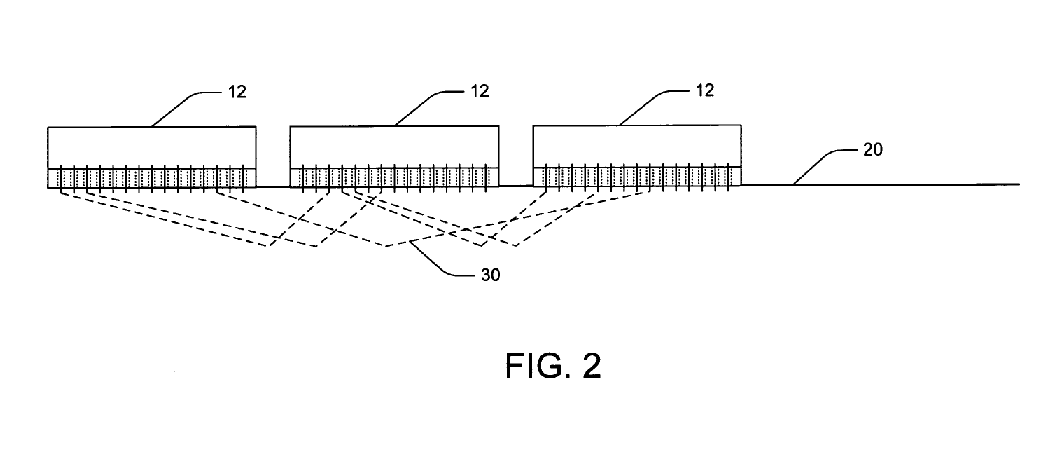

Referring now to the drawings wherein the showings are for purposes of illustrating the exemplary embodiments only and not for purposes of limiting the claimed subject matter, FIG. 1 provides a side view of a system into which the presently described embodiments may be incorporated. As shown generally, FIGS. 1 and 2 illustrate an IC component 12 that includes a plurality of pins 14 that are inserted into receiving channels 16 in an IC socket 18 on a motherboard 20. The IC component can be, for example, a transistor package, a processor component, a memory component, or some other chip that is plugged into the IC socket 18. As shown the IC component 12 is placed the motherboard 20 using the IC socket 18 in a conventional manner, such that a plurality of IC components 12 can be arranged in parallel to disperse heat. Alternatively, the pins 14 can be soldered directly to the motherboard 20. However, such an arrangement typically involves a number of lengthy connections to connect the components according to a specific layout design, as illustrated in FIG. 2.

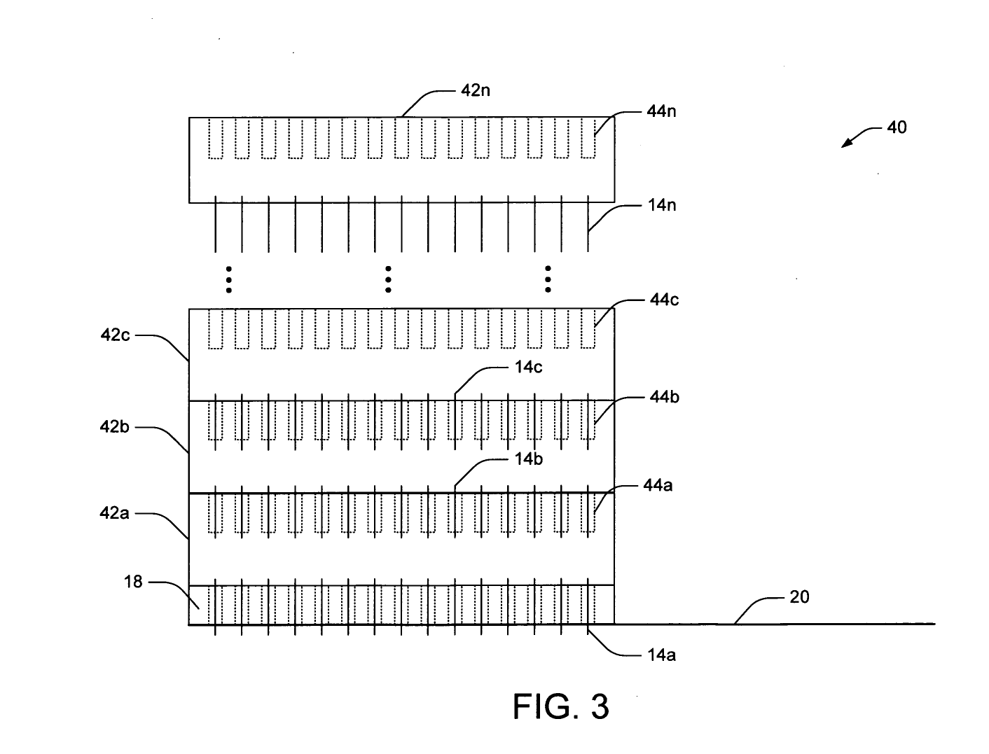

FIG. 2 illustrates a plurality of the IC components 12 arranged on a motherboard 18, with a plurality of interconnections 30 that connect respective pins according to a desired layout. As illustrated, the interconnections 30 can become complex when tens or hundreds of IC components 12 are positioned on the motherboard 20, which in turn complicates design layout and increases power dissipation and heat generation on and around the motherboard 20. As such, it becomes desirable to provide a stackable, modular IC component, which reduces power dissipation and interconnection distance by utilizing an inter-processor bus to connect IC modules, as described below with regard to FIG. 3.

FIG. 3 illustrates an IC component stack 40 that comprises a plurality of IC component modules 42a-42n, which can be connected vertically to reduce interconnection distance and overall device size by mitigating a need for parallel component layout. That is, the stackable modules 42 facilitate IC component layout in the x- and y-planes, but also vertically in the z-plane, thereby introducing an additional dimension to conventional layout design. The z-plane is perpendicular to a motherboard on which the vertical stacks are generated, such that a stack may be horizontal if the motherboard is vertically positioned, etc. Modules 42 have similar or identical configurations with regard to pins 14, receiving channels 44, and general shape, although the contents of respective modules 42 can differ. For instance, given module can house processor circuitry, memory circuitry, heat dissipation components, or any other desired circuitry to provide any desired functionality. Thus, device size can be reduced by using the vertically stacked IC modules, and the device capabilities are scalable in that additional modules (e.g., of memory, processors, etc.) can be easily added to increase device capacity and capability when desired.

Moreover, the stackable modules 42 reduce power consumption by reducing interconnection distances. According to one example, one or more pins 14 for each module 42 can be designated as bus pins that form a continuous connection through all component modules 42 in a stack, in order to permit communication there between and to minimize an amount of power required there for. Additionally, since the interconnections between components are shorter, less power is needed to transmit signals between components, when compared to conventional parallel component layouts. Interconnections between pins 14 from a first modules and a second module can be integrated into the IC module, thereby further reducing power consumption by mitigating interconnection distance. It will be appreciated that the foregoing is but one example of the manner in which IC modules 42 can communicate with one another.

Each module 42 comprises a plurality of IC receiving channels 44 on an upper surface of the module, for receiving a number of pins 14 from another module. For example, a first module 42a can be positioned on a motherboard 20 by inserting its pins 14a into an IC socket 18. In this manner, the pins 14a are connected to a plurality of contacts (not shown) on the motherboard, and connection lines between stacks of modules can be utilized in numbers less than are required for conventional parallel component configurations.

A second module 42b can be coupled to the first module 42a by inserting its pins 14b into IC receiving channels 44a on the top of the first module 42a, and so on, up to an Nth module 42n. Each module has a plurality of integrated interconnections (not shown) that determine pin connections between modules. For instance, pins 14b can connect to contacts for respective interconnections within module 42a, with such interconnections terminating at predefined pins 14a, which in turn are connected to the motherboard 20 via the IC socket 18.

According to an example, module 42a can be a control module or control processor, which, among other functions, detects new modules added to its stack and identifies the new modules and their respective functions (e.g., processor, memory, heat dissipation, other, etc.) Additionally or alternatively, each module 42 can identify itself upon being added to a stack. After initialization protocols (e.g., identification, registration, hand-shaking, etc.), a newly added module (e.g., another processor, memory, heat dissipation element, other) is ready to receive another module as the stack is constructed.

According to another example, the first module 42a is a memory unit, and the second module 42b is a processor unit (e.g., a central processing unit (CPU) or the like). Thus, a modular and scalable system is provided that permits addition of multiple processors, memory elements, heat dissipation elements, or any other suitable computing elements without increasing motherboard size and without requiring replacement modules to add processing power or memory capacity. According to still other aspects, each module has its own control logic and/or circuitry.

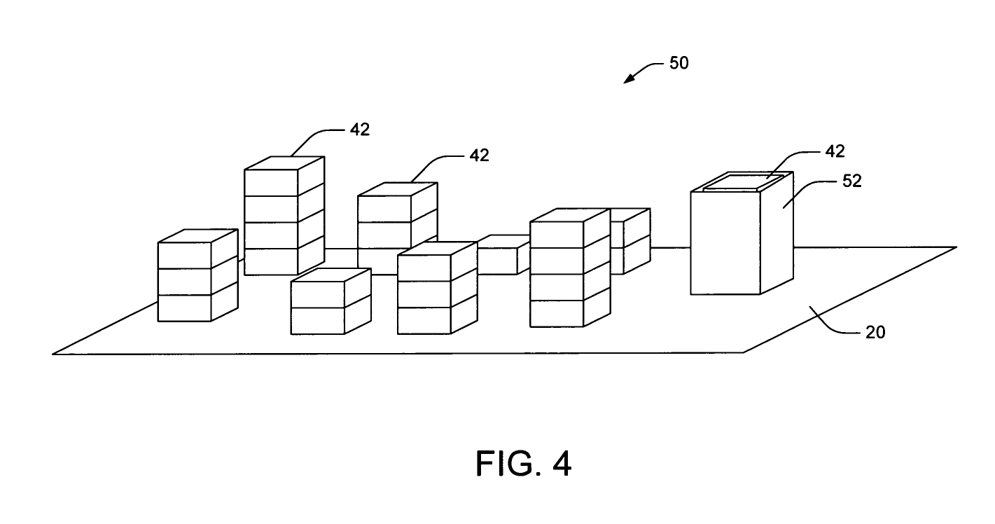

FIG. 4 is an illustration of a plurality of stacks 50 of modules 42 on the motherboard 20, such as can be constructed using the systems and methods described herein. As depicted, the stacks 50 can comprise any desired number of modules 42, such as processors, memory, heat dissipation modules, etc. Moreover, the stacks need not be of the same height, but rather can be of different heights, if desired. In this manner, the modules 42 can be arranged take advantage of traditionally unused space in the z-plane of space within a device in which the stackable modules 42 are employed. A heat dissipation sleeve can be placed over and/or around individual stacks to transfer heat out of and/or away from a given stack 50. The heat dissipation sleeve can comprise heat-dissipative material(s) (e.g., aluminum or some other suitable material) such as will be understood by those of skill. Additionally or alternatively, heat dissipation can be facilitated using one or more systems or methods described below.

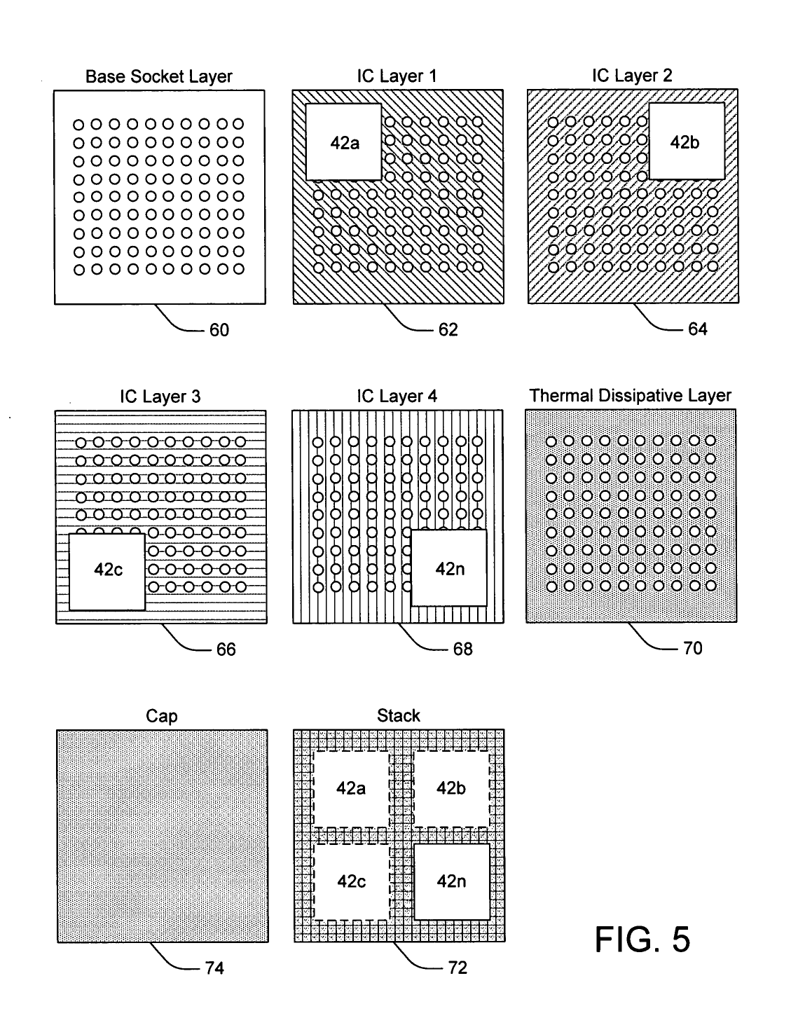

FIG. 5 illustrates a plurality of layers for a stack of IC component modules 42, such as may be employed in conjunction with various aspects described herein. Although in some aspects the modules 42 can be plugged directly into each other, in other aspects a socket layer is interposed between modules. For instance, FIG. 5 illustrates a base socket layer 60 that receives pins from an IC component module 42. According to an example, a first IC module 42a is coupled to a socket layer 62, which may be the same layer as base socket layer 60 or may be an intermediate socket layer. A second IC layer comprises a socket layer 64 and IC module 42b, which is coupled to the socket layer 64 at a different location or quadrant than the quadrant in which the module 42a is coupled to socket layer 62. Similarly, IC module 42c is positioned on socket layer 66, and module 42n on socket layer 68 in respective quadrants, such that when the stack is assembled the IC modules do not overlap. By spacing the IC modules in this manner, heat dissipation is encouraged. Additionally, a thermal dissipative layer 70 is shown, which may be inserted at any level in the stack to facilitate dissipating heat.

The thermal dissipative layer 70 can be formed of any suitable material with heat dissipative properties, as will be understood by those of skill. The thermal dissipative layer 70 has pin-receiving channels on its top surface, which receive pins from a socket layer or module positioned above it, and further has a plurality of pins on its bottom side for connecting to a socket layer or IC module positioned below it. Examples of heat-dissipative materials include, without being limited to, copper, aluminum, etc. Such materials can also be employed to form the heat-dissipative sleeve 52 described above. Furthermore, heat dissipative material can be isolated from pins and/or contact surfaces in pin-receiving channels by an insulating material as will be understood by those of skill in the art.

A stack 72 comprising socket layers 60, 62, 64, 66, and 68, and optionally one or more thermal dissipative layers 70, is shown with respective IC component modules 42a-n. Module 42n is on top of the stack, and modules 42a-c are shown in dashed lines to indicate that they are deeper in the stack. According to an example, module 42a includes an amplifier or the like, which amplifies signals form IC component modules above it. In this manner, individual IC modules can communicate with each other at low power, and the amplifier can boost the signal power when necessary to communicate with other stacks, which may be relatively distant. Additionally, a cap layer 74, without sockets, can be placed atop the stack 72 to reduce unwanted noise or interference that may otherwise occur if sockets on the top of the upper-most module were left open. The cap 74 can be formed of heat dissipative material to further reduce localized heat.

According to other aspects, each socket layer can be formed of heat-dissipative material, and the pin-receiving channels can be formed therein of conductive material. Additionally, more than one module can be placed on each socket layer to further increase spatial efficiency. For example, a module can be positioned in an upper left quadrant and another module can be positioned in a lower right quadrant on the same socket layer. On an overlaying socket layer, modules can be placed in the upper right and lower left quadrants, and such layers can be employed to build a stack with alternating layer patterns so that no two adjacent layers have modules directly above or below one another. It will be appreciated that the socket layers are not limited to having four sections or quadrants, but rather may be divided into any number of sections (e.g., from 1 to N where N is an integer), and can accommodate any number of modules. Additionally, the modules 42 can be any suitable size, such that, for instance, one, two, three, or any other number of modules may occupy all or substantially all of the socket layer surface.

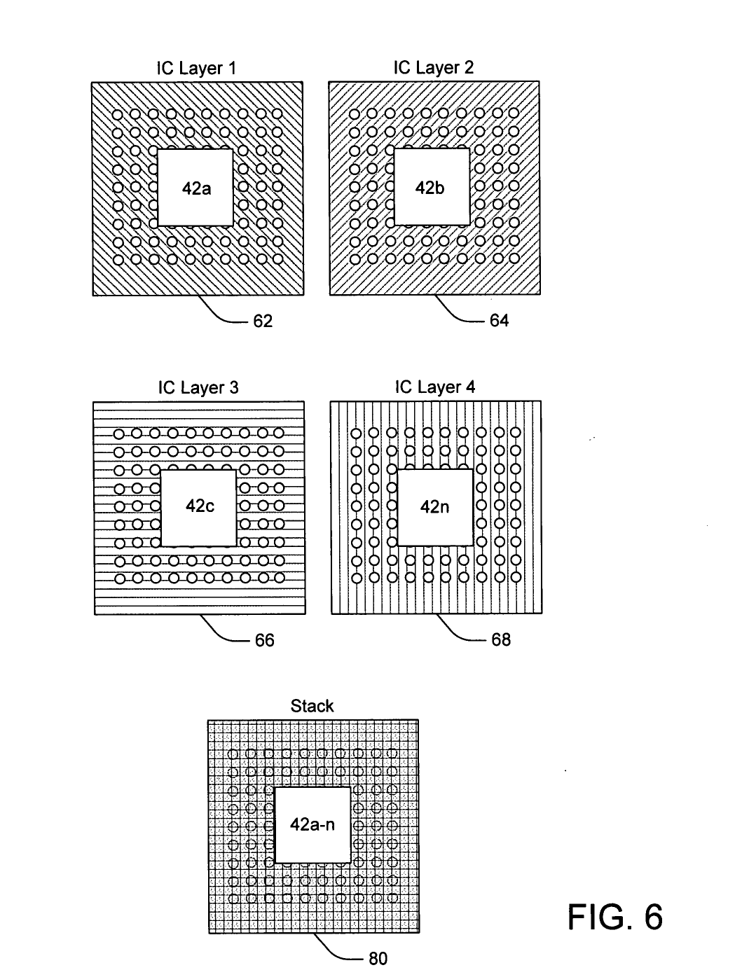

FIG. 6 illustrates an additional or alternative manner of stacking layers and IC modules, in accordance with various aspects described herein. According to the figure, IC modules 42a-n are respectively positioned at the centers of socket layers 62, 64, 66, and 68. The layers are coupled to each other to form the stack 80, with IC module 42n positioned at the top of the stack 80, which may also comprise the base socket layer 60 and one or more thermal dissipative layers 70. In one example, the IC modules are smaller than the socket layers and the space around the IC module, and between the socket layers above and or below the module, permits heat to dissipate from the module. In another example, the modules 42 are larger, approaching the size of the socket layers in the x- and y-dimensions, and a thermal dissipative layer 70 is included above and/or below each module in the stack to facilitate thermal dissipation.

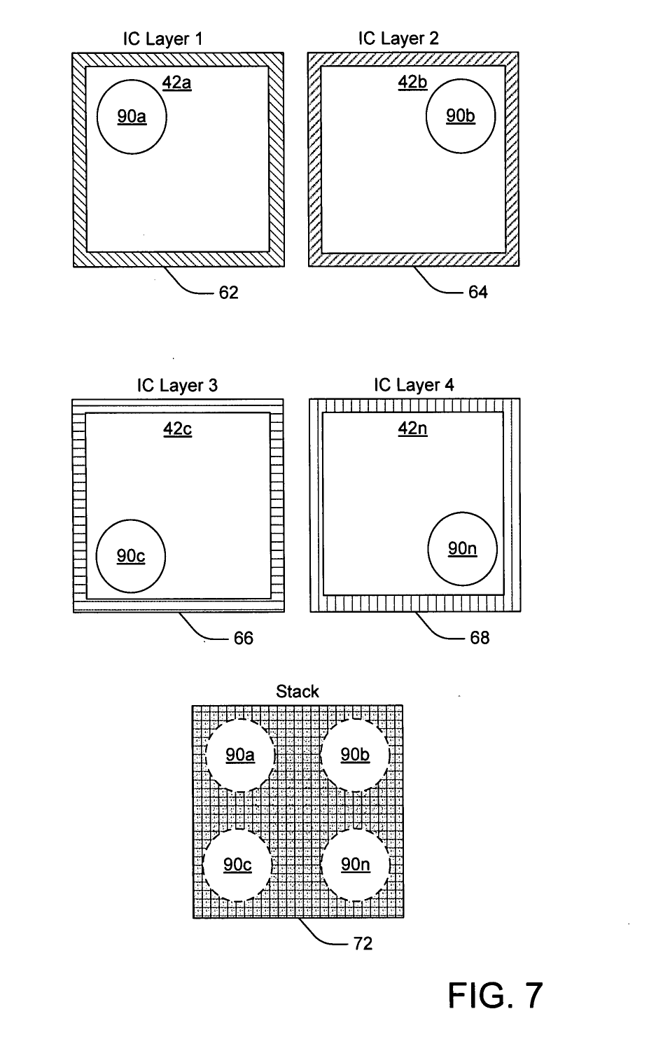

FIG. 7 illustrates another manner in which modules and socket layers can be stacked to facilitate heat dissipation, in accordance with various aspects. According to the figure, each module 42a-n is substantially similar in size to its corresponding socket layer 60, 62, 64, and 66. However, each module 42a-n comprises a heat-producing region 90a-n, respectively. In order to mitigate undesirable accumulation of heat, the regions 90a-n are misaligned in a manner similar to the misalignment of the IC modules of FIG. 5. In this manner, the stack 72 of IC modules and socket layers heat producing regions 90 of respective modules are not positioned directly above or below a heat producing region of a neighboring module. It will be understood that the stack 72 of FIG. 7 may additionally comprise thermal dissipative layers and/or a thermal dissipative cap, as described with regard to preceding figures.

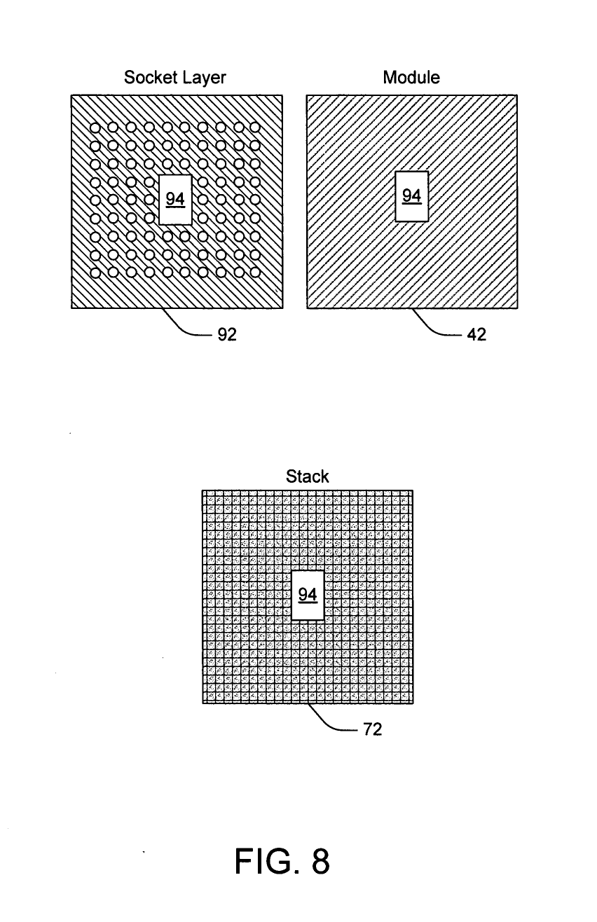

FIG. 8 is an illustration of a further aspect that facilitates heat dissipation, in accordance with one or more features. A socket layer 92 is illustrated, upon which one or more IC modules 42 can be placed to form a stackable layer. The socket layer 92 can be similar or identical to socket layers 60,62, 64, 66, etc., of the preceding figures, except that socket layer 92 has a hole 94 approximately centrally positioned. Similarly, module 42 is depicted with a centralized hole 94, such that when a plurality of socket layers 92 and modules 42 with their centralized holes 94 are coupled together, the hole 94 is maintained in the vertical stack 72, and acts as a chimney through which heat may be vented. Similarly, thermal dissipative layers (not shown) and a thermal dissipative cap (not shown) can be provided with a hole 94 in order to further facilitate heat dissipation. It is to be understood that the hole 94 may be any suitable or desired shape or size.

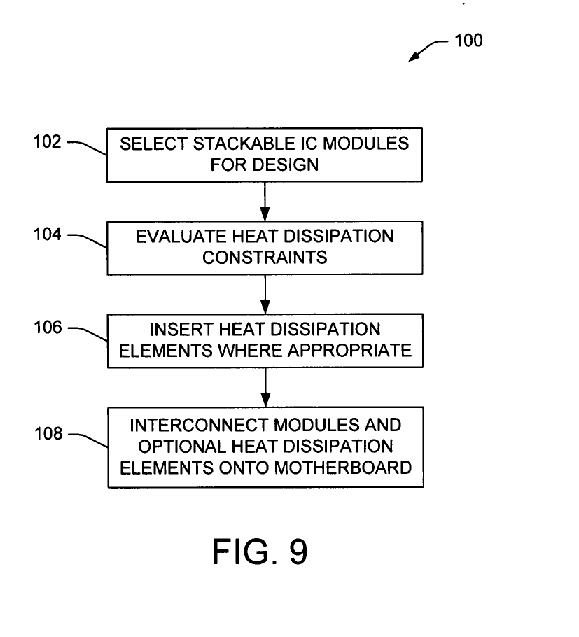

FIG. 9 is an illustration of a method 100 of scalably stacking IC components on a motherboard while providing for heat dissipation, in accordance with various aspects described herein. At 102, stackable IC modules can be selected for a desired design configuration. IC modules may comprise, without being limited to, processors, memory elements, other computing circuitry, communication components (e.g., Bluetooth™ wireless communication components, Zigbee™ wireless communication components, infrared communication components, wired communication components, radio frequency communication components, etc.), or any other IC components that are desired or used on a motherboard.

At 104, heat dissipation constraints can be evaluated to determine whether heat generated by the selected components is above an acceptable threshold level. At 106, heat dissipation elements can be inserted between IC modules where appropriate to maintain a desired level of heat dissipation. For instance, if a processor IC component generates an amount of heat above a predetermined threshold, then a heat dissipation module can be inserted into the stack above and/or below the processor module to ensure that heat generated thereby does not impede the function or performance of an adjacent are nearby module.

At 108, IC modules and optional heat dissipation elements are connected to each other an the stack is mounted or otherwise affixed to the motherboard. According to an example, the ordering of the IC components in the stack is arbitrary and need not follow any prescribed order. In some aspects, it may be desirable to ensure that the heat dissipation elements are placed adjacent to IC components that generate heat above the predetermined acceptable threshold. In other aspects, a control component module may be coupled to the motherboard and the remaining stack may be constructed on top of the control module, as described below.

By connecting the IC modules in a vertical orientation, or stack, on the motherboard, pins that form the interconnection between modules can be regarded as an inter-processor bus, which has a substantially shorter length than conventional parallel interconnections. The shorter inter-processor bus length reduces power dissipation along the connection line, which in turn reduces heat generation and power consumption, making a device employing the stackable and modular IC modules more efficient.

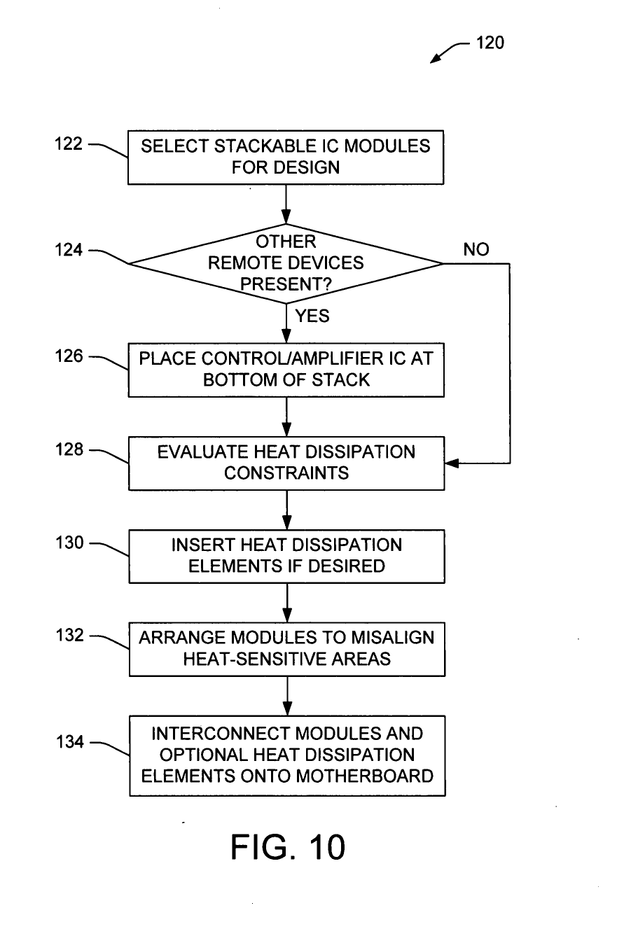

FIG. 10 is an illustration of a method 120 for constructing an IC component stack on a motherboard to minimize motherboard size and reduce interconnection length and power dissipation in a device, in accordance with one or more aspects. At 122, stackable IC modules can be selected according to design constraints. At 124, a determination is made regarding whether one or more remote devices is present. If so, then at 126, a controller or amplifier component can be placed on the motherboard at the bottom of the modules stack to ensure that signals from components in the stack are relayed to and received by other stacks or components therein on the motherboard, and/or to intended recipient devices or components not coupled to the motherboard. The method then proceeds to 128. If no other remote devices are present, then the method proceeds directly to 128, where heat dissipation requirements are evaluated. Heat dissipation elements can be inserted into the stack above or below heat-generating modules to ensure that such heat does not adversely affect nearby IC components, at 130.

IC components may be coupled directly together to form the stack or may be separated by socket layers as described above. IN the latter case, modules can be arranged on their respective socket layers such that no module is directly above or below a neighboring module, such as is described with regard to FIG. 5, at 132. It will be appreciated, however, that in other aspects the IC modules may be centered on their respective socket layers, and thus positioned directly above one another. At 134, all IC modules and respective IC socket layers and/or heat dissipation layers, if any, are interconnected and coupled to the mother board (or control component or amplifier, if present).

The above description merely provides a disclosure of particular embodiments of the invention and is not intended for the purposes of limiting the same thereto. As such, the invention is not limited to only the above-described embodiments. Rather, it is recognized that one skilled in the art could conceive alternative embodiments that fall within the scope of the invention.

We claim:

1. A stackable integrated circuitry (IC) module system, comprising:
a motherboard on which at least one IC module stack is constructed;
a plurality of IC modules coupled together to form the at least one IC module stack, which is coupled to the motherboard; and
an inter-processor bus that is formed by connecting pins of two or more IC modules.

2. The system of claim 1, wherein each IC module comprises processor circuitry.

3. The system of claim 1, wherein each IC module comprises a memory element.

4. The system of claim 1, further comprising a base socket layer, coupled to the motherboard, that receives pins on a first IC module and provides an interconnection between the first IC module and the motherboard.

5. The system of claim 4, wherein the first IC module comprises a controller that governs other IC modules in its stack and amplifies signals there from for transmission to at least one other IC module stack.

6. The system of claim 1, further comprising a socket layer interposed between IC modules to form an interconnection there between.

7. The system of claim 6, wherein IC modules are mounted on respective socket layers in a pattern such that heat-generating regions of neighboring modules are misaligned.

8. The system of claim 6, further comprising at least one heat dissipating element layer interposed between IC modules in the IC module stack.

9. The system of claim 1, further comprising at least one heat dissipation layer that is positioned between IC modules in the IC module stack.

10. The system of claim 1, further comprising a heat-dissipating sleeve that surrounds the IC module stack.

11. A method of scalably stacking IC modules on a motherboard, comprising:
selecting at least two IC modules to be vertically stacked on the motherboard;
evaluating heat dissipation constraints for the IC modules;
inserting a heat dissipating element above or below an IC module that produces heat above a predetermined acceptable threshold level, if present; and
coupling the IC modules and optional heat dissipating element into a vertical stack on the motherboard.

12. The method of claim 11, wherein each IC module comprises one or more of processor circuitry, memory, communication circuitry, or computing circuitry.

13. The method of claim 11, further comprising employing a base socket layer, coupled to the motherboard, which receives pins on a first IC module and provides an interconnection between the first IC module and the motherboard.

14. The method of claim 13, wherein the first IC module comprises a controller that governs other IC modules in its stack and amplifies signals there from for transmission to at least one other IC module stack.

15. The method of claim 11, further comprising interposing socket layers between IC modules to form an interconnection there between.

16. The method of claim 15, further comprising mounting IC modules on respective socket layers in a pattern such that no IC module is positioned directly above or below a neighboring IC module.

17. The method of claim 11, further comprising positioning at least one heat dissipation layer between IC modules in the vertical stack.

18. The method of claim 11, further comprising placing a heat-dissipating sleeve around the vertical stack.

19. The method of claim 11, further comprising scalably adding or removing IC modules to increase at least one of processing power or memory as desired by a user.

20. A system for vertically stacking IC modules on a motherboard, comprising:
a plurality of stackable IC modules;
means for connecting the IC modules into a first vertical stack;
means for communicating between modules within the first vertical stack and with modules in at least a second vertical stack;
means for coupling the first and second vertical stacks to the motherboard; and
means for dissipating heat generated by modules in the first and second vertical stacks.
